(19) United States
(12) Patent Application Publication
(10) Pub. No.: US 2007/0263357 A1
(43) Pub. Date: Nov. 15, 2007

(54) Heat dissipation device

(75) Inventor: Ted Ju, Anloku (TW)

Correspondence Address: BIRCH STEWART KOLASCH & BIRCH, PO BOX 747, FALLS CHURCH, VA, 22040-0747, US

(73) Assignee: Lotes Co., Ltd

(21) Appl. No.: 11/542,187

(22) Filed: Oct. 4, 2006

(30) Foreign Application Priority Data
May 15, 2006 (CN) 200620058909.3

(51) Int. Cl. H05K 7/20

(52) U.S. Cl. 361/702

(57) ABSTRACT

A heat dissipation device is used to dissipate the heat generated from an electronic device. The heat dissipation device includes at least two heat sinks and a heat pipe. Each of the heat sinks respectively contacts with the electronic device. Compared to the prior art, the heat dissipation device, according to the invention, is capable of increasing work efficiency and the life cycle of the chipset.

### BACKGROUND OF THE INVENTION

1. Field of the Invention

The present invention relates to a heat dissipation device.

2. Description of the Prior Art

Current heat dissipation devices, especially the ones used with a south bridge chipset and a north bridge chipset, are generally used for heat dissipation of a chipset. The chipset generally is a north bridge chipset. The heat dissipation device includes two heat sinks and a heat pipe. The heat pipe is used for transferring heat. One of the heat sinks is disposed on the north bridge chipset, and heat is transferred, via the heat pipe, to another heat sink to achieve heat dissipation of the chipset. However, with rapid development of science and technology, working frequency of the south bridge chipset and the north bridge chipset has become higher and higher. Therefore, in the operational process, if only the north bridge chipset is provided with the heat sink and not the south bridge chipset, heat generated from the south bridge chipset cannot be dissipated efficiently. Rising temperature will affect the work efficiency of the south bridge chipset, or even burn out the chipset, and seriously affect the life cycle of the chipset.

Accordingly, it is necessary to design a new type of heat dissipation device to overcome the drawbacks mentioned above.

### SUMMARY OF THE INVENTION

A scope of the present invention is to provide a heat dissipation device. The heat dissipation device is capable of increasing work efficiency and the life cycle of the chipset.

To achieve the objective discussed above, a heat dissipation device, according to the present invention, is used for dissipating heat generated from an electronic device. The heat dissipation device includes at least two heat sinks and a heat pipe, and each of the heat sinks respectively contacts with the electronic device.

Compared to the prior art, the heat dissipation device, according to the invention, is capable of increasing work efficiency and the life cycle of the chipset.

### BRIEF DESCRIPTION OF THE APPENDED DRAWINGS

FIG. 1 is a three dimensional diagram of the heat dissipation device according to the present invention.

FIG. 2 is another three dimensional diagram of the heat dissipation device according to the present invention.

FIG. 3 is a blown-up view of the heat dissipation device according to the present invention.

### DETAILED DESCRIPTION OF THE INVENTION

Figures and an embodiment are described below to provide a more detailed description about the present invention.

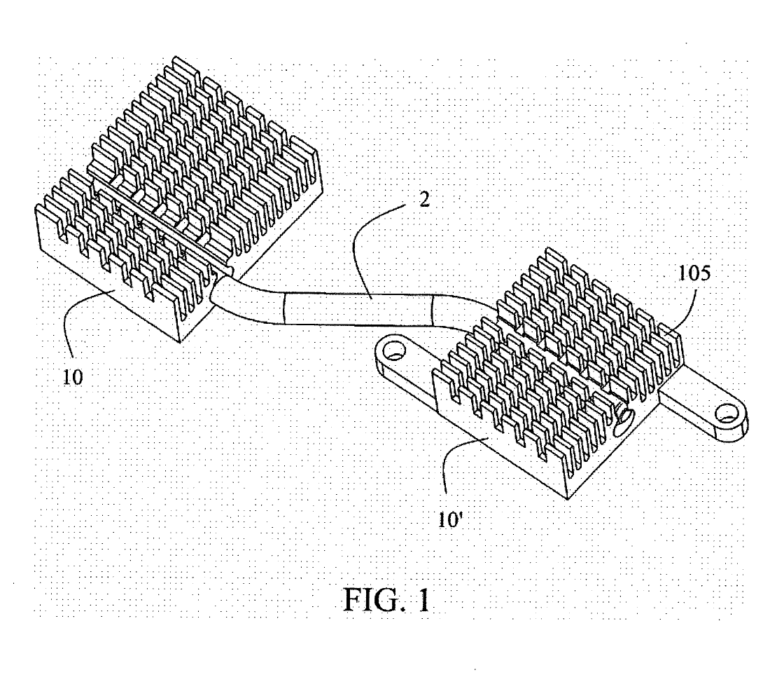

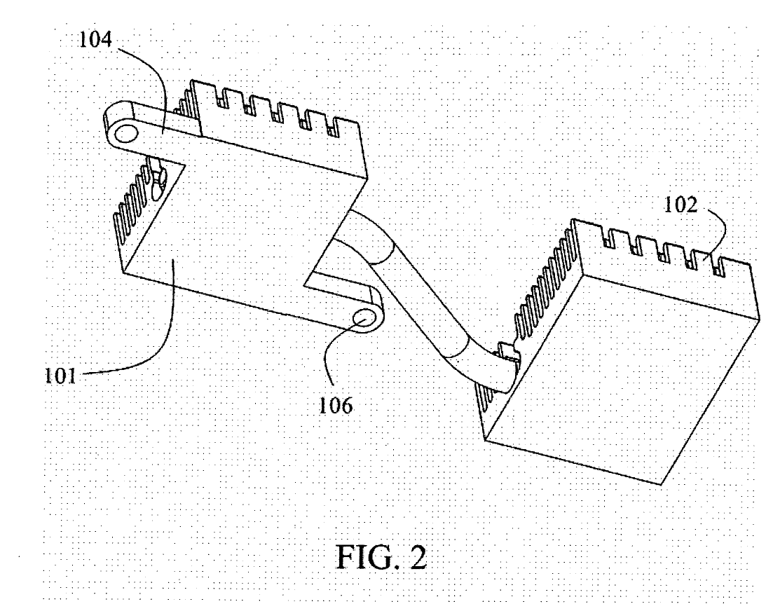

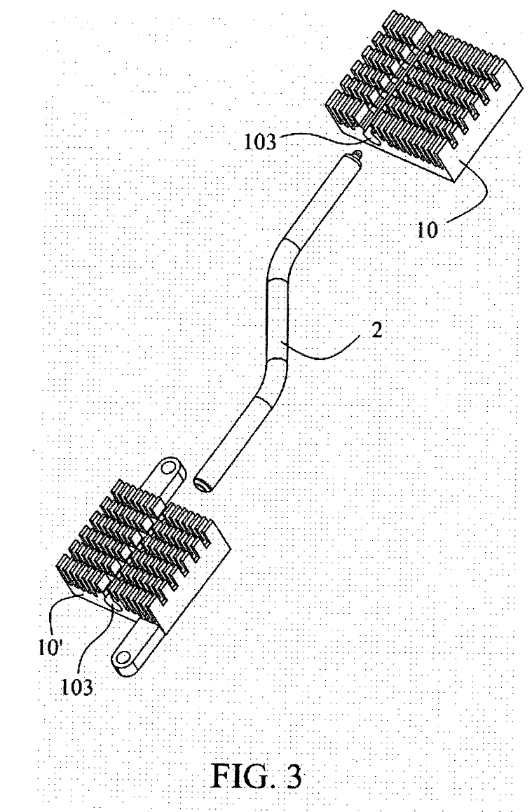

Referring to FIGS. 1 to 3, the heat dissipation device, according to the invention, is used with a south bridge chipset and a north bridge chipset (not shown). The heat dissipation device includes two heat sinks 10,10′ and a heat pipe 2. The two heat sinks 10,10′ respectively contact with the south bridge chipset and the north bridge chipset.

Each of the two heat sinks 10,10′ includes a dissipation base 101, which directly contacts with the south bridge chipset or north bridge chipset, and a plurality of dissipation fins 102, protruding from the dissipation base 101. There are grooves 105 in both cross direction and vertical direction between the dissipation fins 102. To achieve the objective of heat dissipation, each of the two dissipation bases 101 of the two heat sinks 10,10′ has a larger base area than the south bridge chipset and the north bridge chipset.

At least one of the heat sinks 10′ includes two fixing portions 104 for fixing the one heat sink 10′ on a printed circuit board (not shown). In this embodiment, the two fixing portions 104 are disposed on the heat sink 10′, contacted with the north bridge chipset. The two fixing portions 104 are disposed on the two sides of the heat sink 10′ and are arranged in parallel. Each of the two fixing portions 104 has an aperture 106, such that a movable member (not shown), such as a screw, passes through the aperture 106 to connect the heat sink 10′ and the printed circuit board, thus achieving the purpose of fixing the position of the heat sink 10′. On the other hand, each of the two heat sinks 10,10′ has a groove 103, such that the heat pipe 2 is inserted into the groove 103. The heat pipe 2 is curve-shaped. One side of the heat pipe 2 is connected to the heat sink 10′, and the other side of the heat pipe 2 is connected to the heat sink 10. The heat sink 10 can be disposed, by use of glue, on the south bridge chipset to help the south bridge chipset to dissipate heat. Because the heat pipe 2 connects the two heat sinks 10,10′, the heat dissipation device, according to the present invention, is capable of transferring heat from the heat sink with high temperature to the heat sink with low temperature for balancing the temperature between the two heat sink. It makes the two heat sinks dissipate heat uniformly.

The heat dissipation device, according to the present invention, helps two chipsets to dissipate heat at the same time. Under high frequency work of the chipset, the problem of the chipset burning out because of high temperature will not occur. The heat dissipation device, according to the present invention, is capable of increasing work efficiency and life cycle of the chipset.

With the recitations of the preferred embodiment above, the features and spirits of the invention will be hopefully well described. However, the scope of the invention is not restricted by the preferred embodiment disclosed above. The objective is that all alternative and equivalent arrangements are hopefully covered in the scope of the appended claims of the invention. Accordingly, the above disclosure should be construed as limited only by the metes and bounds of the appended claims.

What is claimed is:

1. A heat dissipation device for dissipating the heat generated by an electronic device, said heat dissipation device comprising at least two heat sinks and a heat pipe, said heat dissipation device being characterized in that each of the heat sinks respectively contacts with the electronic device.

2. The heat dissipation device of claim 1, characterized in that at least one of the heat sinks comprises two fixing portions for fixing said one heat sink on a printed circuit board.

3. The heat dissipation device of claim 2, characterized in that the two fixing portions are disposed on both sides of the heat sink.

4. The heat dissipation device of claim 2, characterized in that the two fixing portions are arranged in parallel.

5. The heat dissipation device of claim 2, characterized in that each of the two fixing portions comprises an aperture, such that a movable member passes through the aperture to connect the heat sink and the printed circuit board.

6. The heat dissipation device of claim 1, characterized in that each of the at least two heat sinks comprises a groove, such that the heat pipe is inserted into the groove.

7. The heat dissipation device of claim 1, characterized in that the heat pipe is curve-shaped.

8. The heat dissipation device of claim 1, characterized in that each of the at least two heat sinks comprises a dissipation base and a plurality of dissipation fins protruding from the dissipation base.

9. The heat dissipation device of claim 8, characterized in that there are grooves in cross direction and vertical direction between the dissipation fins.

10. The heat dissipation device of claim 1, characterized in that the heat dissipation device is used for contacting with a south bridge chipset and a north bridge chipset.
